(19) United States
(12) Patent Application Publication
(10) Pub. No.: US 2025/0081535 A1
(43) Pub. Date: Mar. 6, 2025

(54) CRYSTALLINE SPINEL INDIUM-GALLIUM-ZINC-OXIDE CHANNEL

(71) Applicant: Micron Technology, Inc., Boise, ID (US)

(72) Inventors: Adharsh Rajagopal, Boise, ID (US); Scott E. Sills, Boise, ID (US); Yi Fang Lee, Boise, ID (US); Glen H. Walters, Baltimore, MD (US); Alexandre Marc Subirats, Boise, ID (US); Yuanzhi Ma, Boise, ID (US)

(21) Appl. No.: 18/784,338

(22) Filed: Jul. 25, 2024

Related U.S. Application Data
(60) Provisional application No. 63/536,784, filed on Sep. 6, 2023.

(51) Int. Cl. H01L 29/786; H01L 29/423; H01L 29/49; H01L 29/66

(52) U.S. Cl. CPC H10D 30/6755; H10D 30/031; H10D 30/6735; H10D 30/6739; H10D 30/6757

(57) ABSTRACT

Systems, methods and apparatus are provided for transistors having a channel region comprising a crystalline spinel indium-gallium-zinc-oxide (IGZO) material.

### PRIORITY INFORMATION

This application claims the benefit of U.S. Provisional Application No. 63/536,784, filed on Sep. 6, 2023, the contents of which are incorporated herein by reference.

### TECHNICAL FIELD

The present disclosure relates to transistors including a channel region that includes a crystalline spinel indium-gallium-zinc-oxide (IGZO) material.

### BACKGROUND

Memory is one type of integrated circuitry and can be used in computer systems for storing data. Memory may be fabricated in one or more arrays of individual memory cells. Memory cells may be written to, or read from, using digit lines (which may also be referred to as bit lines, data lines, or sense lines) and access lines (which may also be referred to as word lines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A transistor is one type of electronic component that may be used in a memory cell. These transistors can include a pair of conductive source/drain regions having a semiconductive channel region there-between. A conductive gate can be adjacent the channel region and be separated there-from by a thin gate insulator. Application of a suitable voltage to the gate allows current to flow from one of the source/drain regions to the other through the channel region. When the voltage is removed from the gate, current is largely prevented from flowing through the channel region.

Transistors may be used in circuitry other than memory circuitry.

### BRIEF DESCRIPTION OF THE DRAWINGS

FIGS. 1-4 is a view of a portion of an example of a transistor, in accordance with an embodiment of the present disclosure.

FIG. 5 is an example graph of atomic percents of the IGZO material for a transistor, in accordance with an embodiment of the present disclosure.

FIG. 6 is a block diagram illustration of an example apparatus, such as an electronic memory system, in accordance with an embodiment of the present disclosure.

### DETAILED DESCRIPTION

The present disclosure includes apparatuses, methods, and systems for transistors having a first source/drain region, a second source drain/region, and a channel region that includes a crystalline spinel indium-gallium-zinc-oxide (IGZO) material.

Some previous transistors have incorporated indium into gallium-zinc-oxide to provide a channel material, e.g., IGZO. However, these previous IGZO transistors can suffer from reliability issues related to Bias Temperature Instability (BTI). For instance, under BTI stress, devices utilizing these previous IGZO transistors can exhibit an undesirable DVT (ΔV_{T}) turnaround, i.e, reversal in the direction of the DVT shift. However, embodiments of the present disclosure address this issue by utilizing pure crystalline spinel IGZO. Using pure crystalline spinel IGZO thin films for application in TFT devices and providing passivation anneal treatments for reduced defects in the gate material provides better stability for IGZO transistors.

Both a gate oxide and a channel region can be formed from a pure crystalline material, which can provide an improved structure for the transistor and reduce degradation. Passivation anneal treatments can produce one or more buffer layers around the channel region, which can reduce conductivity interference, for example. A crystalline structure can comprise a continuous grain/lattice material for the gate material and the channel. Also, band structure analysis and density of states, which can refer to a number of states per unit energy and per unit volume, analysis can provide that the buffer region has a relatively broader bandgap than the crystalline channel. The buffer can also have a relatively greater work function (eV) than the crystalline channel.

Embodiments of the present disclosure provide that the IGZO material can have a particular atomic percentage to form the crystalline spinel IGZO material. For instance, embodiments provide that the atomic percentage can be from 50 to 76 atomic % gallium, 20 to 50 atomic % zinc, and from 0.01 to 20 atomic % indium, based upon 100 atomic % of metallic elements in the crystalline spinel IGZO material. One or more embodiments provide that atomic percentage can be from 60 to 70 atomic % gallium, 20 to 40 atomic % zinc, and from 0.01 to 15 atomic % indium, based upon 100 atomic % of metallic elements in the crystalline spinel IGZO material. The buffer material can also comprise a gallium zinc oxide (GZO) material. However, the buffer material need not be crystalline and one or more embodiments provide that indium is not utilized, e.g., the buffer material does not include indium. In other embodiments, the buffer material can be crystalline and contain less indium than the channel material.

As mentioned, the crystalline spinel indium-gallium-zinc-oxide (IGZO) material can be utilized to make a transistor, e.g., a thin-film transistor. These transistors can be incorporated in memory structures, memory cells, arrays including such memory cells, memory devices, switching devices, and other semiconductor devices including such arrays, systems including such arrays, and methods for fabricating and using such memory structures are also disclosed. Embodiments of the disclosure include a variety of different memory cells, e.g., volatile memory, non-volatile memory, and/or transistor configurations. Non-limiting examples include random-access memory (RAM), read only memory (ROM), dynamic random access memory (DRAM, synchronous dynamic random access memory (SDRAM), flash memory, resistive random access memory (ReRAM), conductive bridge random access memory (conductive bridge RAM), magnetoresistive random access memory (MRAM), phase change material (PCM) memory, phase change random access memory (PCRAM), spin-torque-transfer random access memory (STTRAM), oxygen vacancy-based memory, programmable conductor memory, ferroelectric random access memory (FE-RAM), reference field-effect transistors (RE-FET), for instance.

The transistors disclosed herein may be used in volatile memory cells, such as dynamic random access memory (DRAM) cells, and may be coupled to a storage element. The storage element may, for example, include storage node, e.g., that can be a capacitor, configured to store a logical state defined by the storage charge in the capacitor. The capacitor may be a capacitor of a one transistor, one capacitor memory cell. In another example, the capacitor may be a capacitor of a two transistor memory cell. Embodiments provide that other types of storage nodes may be utilized.

Some memory devices include memory arrays exhibiting memory cells arranged in a cross-point architecture including conductive lines, e.g., access lines, such as word lines, extending perpendicular, e.g., orthogonal, to additional conductive lines, e.g., data lines, such as digit lines. The memory arrays can be three-dimensional (3D) so as to exhibit multiple decks, e.g., multiple levels, multiple tiers, of the memory cells. Select devices, e.g., transistors as discussed herein, can be used to select particular memory cells of a 3D memory array.

Embodiments of the present disclosure may include different configurations of transistors, e.g., thin-film transistors, including vertically oriented transistors, horizontally oriented transistors, e.g., planar, etc. Embodiments may also include transistors with different gate configurations, including: a single gate, a dual gate and gate all around.

As used herein, “a”, “an”, or “a number of” can refer to one or more of something, and “a plurality of” can refer to two or more such things. For example, a memory device can refer to one or more memory devices, and a plurality of memory devices can refer to two or more memory devices.

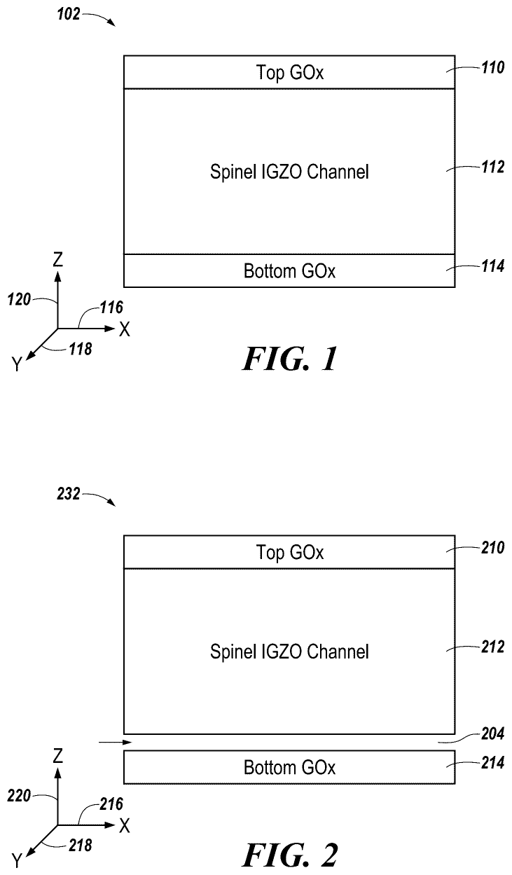

FIG. 1 is a view of a portion of an example of a transistor 102, in accordance with an embodiment of the present disclosure. As shown in FIG. 1, an x-y-z coordinate system includes a horizontal x-direction 116, a horizontal y-direction 118, and a vertical z-direction 120.

Transistor 102 can include a channel region 112. The channel region can formed from a pure crystalline material, which can provide an improved structure for the transistor and reduce degradation. As used herein, a “pure crystalline material” refers to a material including the crystalline components, e.g., pure crystalline IGZO material includes indium, gallium, and zinc oxide. In other words the pure crystalline IGZO material is substantially free from impurities. The crystalline structure can comprise a continuous grain/lattice material for the channel. As mentioned, embodiments provide that the channel region 112 includes the crystalline spinel IGZO material, as discussed herein. The crystalline spinel IGZO material can be a pure crystalline material. In one embodiment, the channel region can have a thickness in a range of 150-250 angstroms (A). However embodiments are not so limited. One or more embodiments provide that the channel region has a thickness of 200 A.

One or more embodiments provided that the transistor 102 can include a gate material. The gate material may be adjacent the channel region 112. As illustrated in FIG. 1, the gate material can include a first gate material 110 and a second gate material 114. The channel region 112 can be between the first gate material 110 and the second gate material 114.

The first gate material 110 and the second gate material 114 can be an aluminum oxide material (AlOx), a hafnium oxide material, or a silicon oxide material, among other materials.

The gate materials can be formed from a pure crystalline material and may comprise a continuous grain/lattice material. In one embodiment, the gate materials can each have a respective thickness in a range of 30-70 A. For example, the first gate material 110 can have a thickness in a range of 30-70 A, while the second gate material 114 can also have a thickness in a range of 30-70 A. However embodiments are not so limited. One or more embodiments provide that the first gate material 110 and the second gate material 114 each have a respective thickness of 50 A.

While not shown in FIG. 1, transistor 102 can include a first source/drain region and a second source/drain region. One or more embodiments provide that at least one of the first source/drain region and the second source/drain region includes the IGZO material. One or more embodiments provide that both of the first source/drain region and the second source/drain region include the IGZO material. While first and second source/drain region references are used herein to denote two separate and distinct source/drain regions, it is not intended that the source/drain region referred to as the “first” and/or “second” source/drain regions have some unique meaning. The first source/drain region and the second source/drain region may respectively be formed from a doped semiconductor material, e.g., Si, SiGe, Ge, SiCo, Transition Metal Dichalcogenides (TMD), a metal, and/or metal composite materials containing ruthenium (Ru), molybdenum (Mo), nickel (Ni), titanium (Ti), copper (Cu), a doped conducting oxide, such as indium tin oxide (ITO), indium oxide, or semiconducting oxides like IGZO, IZO, SnZnO, among other materials. The first source/drain region and a second source/drain region can be formed adjacent the channel region 112.

FIG. 2 is a view of a portion of an example of a transistor 232, in accordance with an embodiment of the present disclosure. FIG. 2 includes an x-y-z coordinate system including a horizontal x-direction 216, a horizontal y-direction 218, and a vertical z-direction 220.

The channel region 212 of FIG. 2 can be similar or analogous to the channel region 102 of FIG. 1. The first gate material 210 of FIG. 2 can be similar or analogous to first gate material 110 of FIG. 1. The second gate material 214 of FIG. 2 can be similar or analogous to second gate material 114 of FIG. 1.

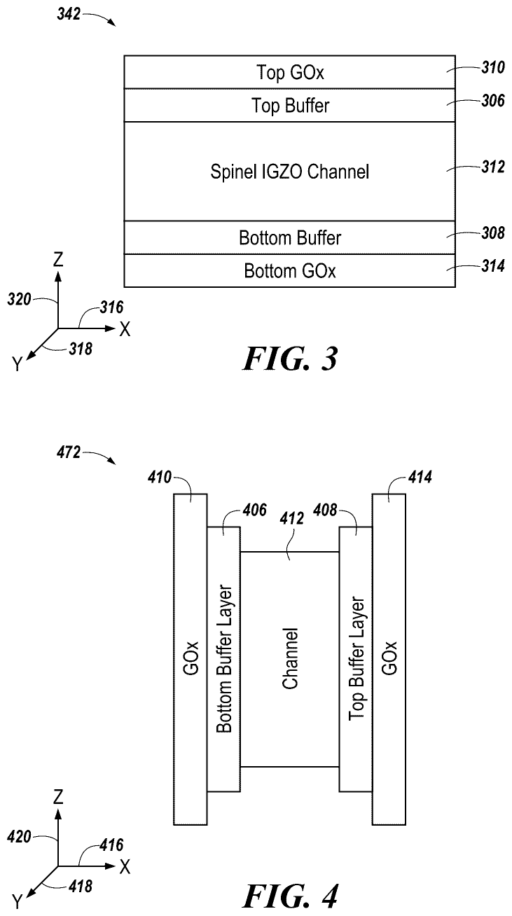

A passivation anneal treatment 204 may be applied to one or more portions of the transistor 232 to provide a buffer region (described in more detail in FIG. 3) around the channel region 112. Embodiments provide that the passivation anneal treatment 204 disclosed herein and/or devices including the transistors may be made using various processing techniques such as rapid thermal processing, atomic material deposition (ALD), physical vapor deposition (PVD), chemical vapor deposition (CVD), supercritical fluid deposition (SFD), patterning, etching, filling, chemical mechanical planarization (CMP), combinations thereof, and/or other suitable processes. In accordance with a number of embodiments of the present disclosure, materials may be grown in situ. The passivation anneal treatment does not reduce the thickness of the channel region 212, the first gate material 110, or the second gate material 114.

The passivation anneal treatment 204 can be applied adjacent the channel region 212 and the second gate material 214. One or more embodiments provide that the buffer region can be formed with rapid thermal processing. The rapid thermal processing can occur at a temperature of a range from 750 to 1,000° C. in a time period of a range from 5 to 60 seconds, among other values.

FIG. 3 is a view of a portion of an example of a transistor 342, in accordance with an embodiment of the present disclosure. FIG. 3 includes an x-y-z coordinate system including a horizontal x-direction 316, a horizontal y-direction 318, and a vertical z-direction 320.

The channel region 312 of FIG. 3 can be similar or analogous to channel region 112 and 212 of FIGS. 1 and 2 respectively. The first gate material 310 of FIG. 3 can be similar or analogous to first gate material 110 and 210 of FIGS. 1 and 2 respectively. The second gate material 314 of FIG. 3 can be similar or analogous to second gate material 114 and 214 of FIGS. 1 and 2 respectively.

Transistor 342 may include a buffer material. The buffer material may be adjacent the channel region 312. As illustrated in FIG. 3, the buffer material may include a first buffer region 306 and a second buffer region 308. The channel region 312 can be between the first buffer region 306 and the second buffer region 308. For example, the first buffer region 306 can be adjacent the first gate material 310 while the second buffer region 308 can be adjacent the second gate material 314.

The first buffer region 306 and the second buffer region 308 can respectively passivate defects within the first gate material 310 and the second gate material 314. For example, formation of the first buffer region 306 and the second buffer region 308 can reduce conductivity between the channel region 312 and the gate materials 310 and 314. The first buffer region 306 and the second buffer region 308 can also improve the positive bias temperature instability (PBTI) of the transistor 342.

The buffer material for first buffer region 306 and second buffer region 308 can be formed from a gallium zinc oxide (GZO) material. In some embodiments, the buffer material for first buffer region 306 and second buffer region 308 can be formed from a relatively less conductive material than the gate materials and/or channel material. One or more embodiments provide that the buffer material may not be formed from a crystalline material.

In one embodiment, the buffer regions can each respectively have a thickness in a range from 30-70 A. For example, the first buffer region 306 can have a thickness in a range from 30-70 A while the second buffer region 308 can also comprise a thickness in a range of 30-70 A. However embodiments are not so limited. In some embodiments, the first buffer region 306 can have a thickness similar, e.g., the same as, to the first gate material 310 while the second buffer region 308 can have a thickness similar, e.g., the same as, to the second gate material 314. One or more embodiments provide that the first buffer region 306 and the second buffer region 308 each have a respective thickness in a range from 30-70 A.

FIG. 4 is a view of a portion of an example of a transistor 472, in accordance with an embodiment of the present disclosure. FIG. 4 includes an x-y-z coordinate system including a horizontal x-direction 416, a horizontal y-direction 418, and a vertical z-direction 420. FIG. 4 may be a different view of the transistor shown in FIG. 3.

The channel region 312 of FIG. 3 can be similar or analogous to channel region 112 and 212 of FIGS. 1 and 2 respectively. The first gate material 310 of FIG. 3 can be similar or analogous to first gate material 110 and 210 of FIGS. 1 and 2 respectively. The second gate material 314 of FIG. 3 can be similar or analogous to second gate material 114 and 214 of FIGS. 1 and 2 respectively.

Transistor 472 may include a first gate material 410 and a second gate material 414. The gate materials can be formed from materials as discussed in FIG. 1. Transistor 472 may include a channel region 412. The channel region 412 can be formed from materials as discussed in FIG. 1. Transistor 472 may include a first buffer region 406 and a second buffer region 408. The buffer regions can be formed from materials, as discussed in FIG. 3. While not shown in FIG. 4, transistor 472 may include a first source/drain region and a second source/drain region. The first source/drain region and a second source/drain region can be formed adjacent the channel region 412.

Embodiments of the present disclosure are not limited to the physical structure of transistors shown in FIGS. 1-4. For instance, in a number of embodiments, the structure of a transistor may include one or more additional components and/or may have a differing arrangement of materials.

As an example, the transistors disclosed herein and/or devices including the transistors may be made by forming a material stack, e.g., on a substrate, including a number of the channel region, the first source/drain material, the second source/drain material, and the gate material. The material stack may include one or more additional materials utilized for transistor, and/or devices including transistors, fabrication. Processing steps can include, among others, patterning and etching the material stack, selectively removing a portion of one or more materials, depositing a material, and planarization to make transistors disclosed herein and/or devices including the transistors.

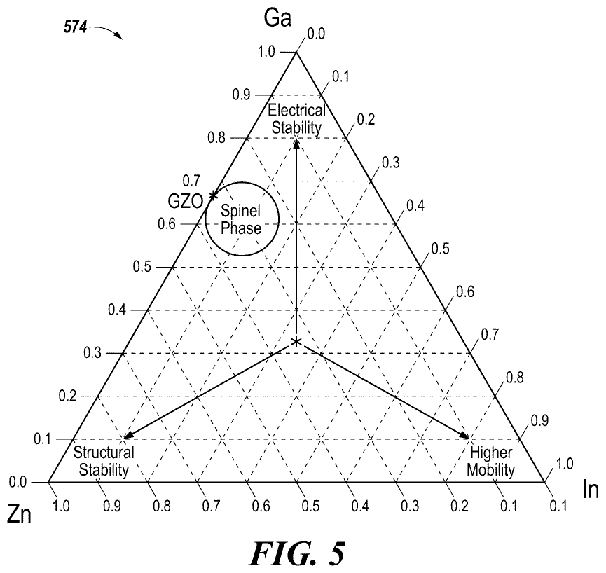

FIG. 5 an example graph 574 of atomic percents of the IGZO material for a transistor, in accordance with an embodiment of the present disclosure. As mentioned, embodiments provide that the channel region comprises a crystalline spinel IGZO material. The channel region can be formed from materials, as discussed in FIGS. 1-4, e.g., according to graph 574.

As previously mentioned, the channel region may be formed from a material comprising 50 to 76 atomic % gallium, 20 to 50 atomic % zinc, and from 0.01 to 20 atomic % indium, based upon 100 atomic % of metallic elements in the crystalline spinel IGZO material as illustrated in FIG. 5. One or more embodiments provide that atomic percentage can be from 60 to 70 atomic % gallium, 20 to 40 atomic % zinc, and from 0.01 to 15 atomic % indium, based upon 100 atomic % of metallic elements in the crystalline spinel IGZO material. The crystalline structure of the channel can provide better stability and structure for the channel region and prevent degradation. The crystalline structure formed utilizing atomic percentages according to this graph, as discussed herein, may be a continuous grain/lattice material.

The transistor as formed can cause the work function for the first gate material and the second gate material to be relatively greater than the work function for the channel region. The first gate material and the second gate material can have a work function in a range from 6.0 eV to 7 eV while the channel region can have a work function in a range from 3.0 eV to 3.8 eV.

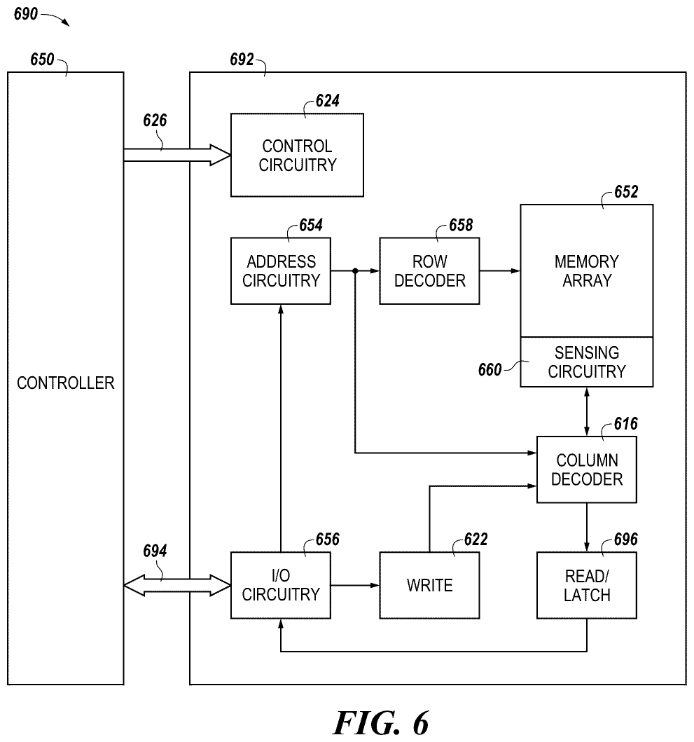

FIG. 6 is a block diagram illustration of an example apparatus, such as an electronic memory system 690, in accordance with an embodiment of the present disclosure. Memory system 690 may include an apparatus, such as a memory device 692 and a controller 650, such as a memory controller, e.g., a host controller. Controller 650 might include a processor, for example. Controller 650 might be coupled to a host, for example, and may receive command signals (or commands), address signals (or addresses), and data signals (or data) from the host and may output data to the host.

Memory device 692 includes a memory array 652 of memory cells. For example, memory array 652 may include one or more of the memory arrays, such as a cross-point array, among other types arrays. The memory array 652 may include a number of transistors, e.g., access devices where the channel region includes a crystalline spinel IGZO material, as disclosed herein. Memory device 692 may include address circuitry 654 to latch address signals provided over I/O connections 694 through I/O circuitry 656. Address signals may be received and decoded by a row decoder 658 and a column decoder 616 to access the memory array 652.

Memory device 692 may sense, e.g., read, data in memory array 652 by sensing voltage and/or current changes in the memory array columns using sense/buffer circuitry that in some examples may be read/latch circuitry 696. Read/latch circuitry 696 may read and latch data from the memory array 652. Sensing circuitry 660 may include a number of sense amplifiers coupled to memory cells of memory array 652, which may operate in combination with the read/latch circuitry 696 to sense, e.g., read, memory states from targeted memory cells. I/O circuitry 656 may be included for bi-directional data communication over the I/O connections 694 with controller 650. Write circuitry 622 may be included to write data to memory array 652.

Control circuitry 624 may decode signals provided by control connections 626 from controller 650. These signals may include chip signals, write enable signals, and address latch signals that are used to control the operations on memory array 652, including data read and data write operations.

Control circuitry 624 may be included in controller 650, for example. Controller 650 may include other circuitry, firmware, software, or the like, whether alone or in combination. Controller 650 may be an external controller, e.g., in a separate die from the memory array 652, whether wholly or in part, or an internal controller, e.g., included in a same die as the memory array 652. For example, an internal controller might be a state machine or a memory sequencer.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combination of the above embodiments, and other embodiments not specifically described herein will be apparent to those of ordinary skill in the art upon reviewing the above description. The scope of a number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A transistor comprising:
a gate material;
a channel region comprising a crystalline spinel indium-gallium-zinc-oxide (IGZO) material adjacent the gate material; and
a buffer material located between the channel region and the gate material.

2. The transistor of claim 1, wherein the channel region comprises from 50 to 76 atomic % gallium.

3. The transistor of claim 2, wherein the channel region comprises from 20 to 50 atomic % zinc.

4. The transistor of claim 1, wherein the transistor comprises one of a single gate, a dual gate, and gate all around.

5. The transistor of claim 1, wherein the transistor is coupled to one of a capacitor of a one transistor, one capacitor memory cell (1t1c) and a two transistor memory cell.

6. The transistor of claim 1, wherein the channel region has a thickness in a range of 150-250 angstroms (A).

7. The transistor of claim 1, wherein the buffer material comprises a gallium-zinc-oxide (GZO) material.

8. The transistor of claim 7, wherein the buffer material has a thickness of 30-70 angstroms (A).

9. The transistor of claim 1, a first source/drain region and a second source/drain region is adjacent the channel region.

10. A transistor comprising:
a gate material;
a channel region comprising an indium-gallium-zinc-oxide (IGZO) material adjacent the gate material wherein the channel region comprises gallium in a range from 50 to 76 atomic %; and
a buffer region located between the channel region and the gate material.

11. The transistor of claim 10, wherein the gate material is a crystalline aluminum oxide (AlOx) material.

12. The transistor of claim 10, wherein the channel region is between the gate material and a second gate material.

13. The transistor of claim 12, wherein a second buffer region is formed adjacent the second gate material.

14. The transistor of claim 10, wherein the thickness of the gate material is in a range between 30-70 angstroms (A).

15. A method of making a transistor, the method comprising:
forming a first gate oxide material;
forming a channel region comprising a crystalline spinel indium-gallium-zinc-oxide (IGZO) material between the first gate oxide material and a second gate oxide material wherein the channel region comprises from 50 to 76 atomic % gallium, 20 to 50 atomic % zinc and from 0.01 to 20 atomic % indium;
forming a first buffer region between the first gate oxide material and the channel region; and
forming a second buffer region between the second gate oxide material and the channel region.

16. The method of claim 15, wherein forming the first buffer region includes using a passivation anneal treatment.

17. The method of claim 15, wherein forming the first buffer region includes using rapid thermal processing.

18. The method of claim 15, wherein forming the first buffer region includes using rapid thermal processing at 750-1000° C. for from 5 to 60 seconds.

19. The method of claim 15, wherein forming the first buffer region includes using one of an atomic layer deposition, physical vapor deposition, and a chemical vapor deposition.

20. The method of claim 15, wherein forming the transistor includes an effective work function for the first gate oxide material and the second gate oxide material in a range between 6.0 eV to 7 eV and the channel region includes an effective work function in a range between 3.0 eV to 3.8 eV.
